(19) United States
(12) Patent Application Publication
(10) Pub. No.: US 2025/0323531 A1
(43) Pub. Date: Oct. 16, 2025

(54) METHOD AND APPARATUS FOR DETECTING FOREIGN OBJECTS USING VARIABLE MONITORING AREA IN WIRELESS CHARGING SYSTEM

(71) Applicant: ELECTRONICS AND TELECOMMUNICATIONS RESEARCH INSTITUTE, Daejeon (KR)

(72) Inventors: Gwangzeen KO, Daejeon (KR); Sang-Won KIM, Daejeon (KR); Seong-Min KIM, Daejeon (KR); Kyeseok YOON, Daejeon (KR); In Kui CHO, Daejeon (KR)

(73) Assignee: ELECTRONICS AND TELECOMMUNICATIONS RESEARCH INSTITUTE, Daejeon (KR)

(21) Appl. No.: 19/082,404

(22) Filed: Mar. 18, 2025

(30) Foreign Application Priority Data
Apr. 11, 2024 (KR) 10-2024-0048784

(51) Int. Cl. H02J 50/60; G01R 33/02; G06V 10/75; G06V 10/82; G06V 20/52; H02J 50/10

(52) U.S. Cl. CPC H02J 50/60; G01R 33/02; H02J 50/10; G06V 10/751; G06V 10/82; G06V 20/52

(57) ABSTRACT

A foreign object detection method may comprise: acquiring a transmission current value of a wireless power transmitter; calculating the magnitude of a magnetic field based on the acquired transmission current value; setting a monitoring area formed between the wireless power transmitter and a wireless power receiver according to the calculated magnitude of the magnetic field; acquiring an image and determining whether a foreign object is present in the image; generating information about the foreign object upon determining that the foreign object is present in the image; and determining whether the foreign object is included in the monitoring area based on the information about the foreign object.

### CROSS-REFERENCE TO RELATED APPLICATIONS

This application claims priority to Korean Patent Application No. 10-2024-0048784, filed on Apr. 11, 2024, with the Korean Intellectual Property Office (KIPO), the entire contents of which are hereby incorporated by reference.

### BACKGROUND

### 1. Technical Field

The present disclosure relates to a foreign object detection method and apparatus, and more particularly, to a technology for detecting foreign objects using a variable monitoring area in a wireless charging system.

### 2. Related Art

A wireless charging system includes a wireless charging transmitter and a wireless charging receiver. Here, the space between the coil of the wireless charging transmitter and the coil of the wireless charging receiver can be referred to as the charging area. If a metallic object enters the charging area, it may alter the resonance frequency, reducing transmission efficiency, or cause unintended magnetic induction, potentially leading to a fire, thereby significantly compromising system stability.

Additionally, if a part of a human body, such as a worker's hand, or a living organism, such as an animal, enters the charging area, it may cause harm, which is why wireless power transfer standards classify both metallic objects and living organisms as foreign objects and define requirements for their accurate detection.

### SUMMARY

It is an object of the present disclosure to provide a method and apparatus for detecting foreign objects.

It is another object of the present disclosure to provide foreign object detection method and apparatus capable of setting or updating a charging area in a wireless charging system based on variations in charging current and magnetic field strength. That is, the foreign object detection method and apparatus of the present disclosure are capable of accurately detecting foreign objects by reducing the false detection rate caused by the limitations of conventional fixed or planar monitoring areas.

Furthermore, it is still another object of the present disclosure to provide a foreign object detection method and apparatus capable of ensuring foreign object detection accuracy by determining whether a foreign object is within the monitoring area.

According to an exemplary embodiment of the present disclosure, a foreign object detection method may comprise: acquiring a transmission current value of a wireless power transmitter; calculating a magnitude of a magnetic field based on the acquired transmission current value; setting a monitoring area formed between the wireless power transmitter and a wireless power receiver according to the calculated magnitude of the magnetic field; acquiring an image and determining whether a foreign object is present in the image; generating information about the foreign object when it is determined that the foreign object is present in the image; and determining whether the foreign object is included in the monitoring area based on the information about the foreign object.

The foreign object detection method may further comprise: stopping transmission power of the wireless power transmitter upon determining that the foreign object is included in the monitoring area.

The setting of the monitoring area may comprise: setting or updating the monitoring area using three-dimensional spatial variables based on a shape of a coil of the wireless power transmitter and the magnitude of the magnetic field.

The information about the foreign object may include an angle between a centerline of a camera capturing an area including the monitoring area and a center point of a virtual foreign object projected onto a reference plane, and a distance between the camera and the foreign object, and the determining of whether the foreign object is included in the monitoring area may be based on the angle and the distance.

The determining of whether the foreign object is present in the image may comprise: comparing corresponding pixels between the acquired image and a pre-stored image without any foreign object; detecting the number of pixels among the compared pixels that have different values; and determining that the foreign object is present in the image when the number of detected pixels is greater than or equal to a predetermined number of pixels.

The camera may be a distortion-free lens, and the generating of the information about the foreign object may comprise: calculating the distance between the camera and an actual foreign object based on the number of pixels of the virtual foreign object projected onto the reference plane in the image, the number of pixels of the actual foreign object, and a distance between the camera and the reference plane; and calculating the angle between the centerline of the camera and the center point of the virtual foreign object projected onto the reference plane in the image, based on the camera's field of view and the number of pixels in a reference direction of the image.

The generating of the information about the foreign object may comprise: inputting the image containing the foreign object into an artificial neural network to obtain a type of the foreign object; and determining a value of the pre-measured actual length corresponding to type of the obtained foreign object as the number of pixels of the actual foreign object, using a value of a pre-measured actual length for each type.

The camera may be a distorted lens, and the generating of the information about the foreign object may comprise: calculating the distance between the camera and the foreign object using an interpolation method based on a distance between the camera and the reference plane and the pre-measured length of the virtual foreign object projected onto the reference plane for each type of foreign object.

A lens of the camera, the monitoring area, and the reference plane may be positioned in a straight line, and the wireless power transmitter may be spaced apart by a predetermined distance from the reference plane.

The foreign object detection method of may further comprise: generating a foreign object detection alarm upon determining that the foreign object is included in the monitoring area.

According to another exemplary embodiment of the present disclosure, a foreign object detection apparatus may comprise: a processor configured to acquire a transmission current value of a wireless power transmitter, calculate a magnitude of a magnetic field based on the acquired transmission current value, set a monitoring area formed between the wireless power transmitter and a wireless power receiver according to the calculated magnitude of the magnetic field, acquire an image and determine whether a foreign object is present in the image, generate information about the foreign object when it is determined that the foreign object is present in the image, and determine whether the foreign object is included in the monitoring area based on the information about the foreign object.

Transmission power of the wireless power transmitter may be cut off upon determining that the foreign object is included in the monitoring area.

The processor may set or update the monitoring area by defining the monitoring area as a three-dimensional spatial variable based on a shape of a coil of the wireless power transmitter and the magnitude of the magnetic field.

The foreign object detection apparatus may further comprise a camera, wherein the image may be captured by the camera, and the information about the foreign object may include an angle between the centerline of the camera that captures an area including the monitoring area and a center point of the virtual foreign object projected onto a reference plane and the distance between the camera and the foreign object, and the processor may determine whether the foreign object is included in the monitoring area based on the angle and the distance.

When determining whether the foreign object is present in the image, the processor may compare corresponding pixels between the acquired image and a pre-stored image without any foreign object, detect the number of pixels among the compared pixels that have different values, and determine that the foreign object is present in the image when the number of detected pixels is greater than or equal to a predetermined number of pixels.

The camera may be a distortion-free lens, and the processor may calculate the distance between the camera and an actual foreign object based on the number of pixels of the virtual foreign object projected onto the reference plane in the image, the number of pixels of the actual foreign object, and a distance between the camera and the reference plane, and calculate the angle between the centerline of the camera and the center point of the virtual foreign object projected onto the reference plane in the image, based on the camera's field of view and the number of pixels in a reference direction of the image.

The foreign object detection apparatus may further comprise an artificial neural network, wherein the processor may input the image containing the foreign object into the artificial neural network to obtain a type of the foreign object, and determine a value of a pre-measured actual length corresponding to the type of the obtained foreign object as the number of pixels of the actual foreign object using a value of a pre-measured actual length for each type.

The camera may be a distortion lens, and the processor may calculate the distance between the camera and the foreign object using an interpolation method based on a distance between the camera and the reference plane and the pre-measured length of the virtual foreign object projected onto the reference plane for each type of foreign object.

A lens of the camera, the monitoring area, and the reference plane may be positioned in a straight line, and the wireless power transmitter may be spaced apart by a predetermined distance from the reference plane.

The processor may generate a foreign object detection alarm upon determining that the foreign object is included in the monitoring area.

The present disclosure advantageously provides a method and apparatus for detecting foreign objects.

The foreign object detection method and apparatus of the present disclosure are advantageous in terms of updating a changing charging area in a wireless charging system. That is, the foreign object detection method and apparatus of the present disclosure are capable of reducing the false detection rate of foreign objects caused by the limitations of conventional fixed or planar monitoring areas.

The foreign object detection method and apparatus of the present disclosure are advantageous in terms of improving foreign object detection accuracy by determining whether a foreign object is within the monitoring area.

The foreign object detection method and apparatus of the present disclosure are advantageous in terms of ensuring the stability of the wireless power transfer system by precisely defining and managing the charging area through a variable monitoring area set based on the transmission current value.

The foreign object detection method and apparatus of the present disclosure are advantageous in terms of improving foreign object detection accuracy by eliminating false detection probability, based on evaluating whether the foreign object is within the monitoring area in a three-dimensional manner, rather than relying on a planar image.

The foreign object detection method and apparatus of the present disclosure are advantageous in terms of detecting the foreign object precisely regardless of the level of distortion of the imaging device.

The foreign object detection method and apparatus of the present disclosure are advantageous in terms of being implemented economically using a single imaging device to detect the three-dimensional monitoring area.

### BRIEF DESCRIPTION OF DRAWINGS

FIG. 1 is a diagram illustrating a wireless charging system according to an embodiment of the present disclosure.

FIG. 2 is a diagram illustrating how the charging area varies with the shape of the coil and the current value, according to an embodiment of the present disclosure.

FIG. 3 is a diagram illustrating the problem when monitoring the charging area based on images according to a conventional technology.

FIG. 4 is a diagram illustrating a foreign object detection system according to an embodiment of the present disclosure.

FIG. 5 is a flowchart illustrating the foreign object detection method according to an embodiment of the present disclosure.

FIG. 6 is a flowchart illustrating the process of monitoring foreign objects according to an embodiment of the present disclosure.

FIG. 7 is a diagram illustrating the process of generating information about foreign objects according to an embodiment of the present disclosure.

FIG. 8 is a conceptual diagram illustrating an example of a generalized foreign object detection apparatus or computing system capable of performing at least some of the processes from FIGS. 1 to 7.

### DETAILED DESCRIPTION OF THE EMBODIMENTS

While the present disclosure is capable of various modifications and alternative forms, specific embodiments thereof are shown by way of example in the drawings and will herein be described in detail. It should be understood, however, that there is no intent to limit the present disclosure to the particular forms disclosed, but on the contrary, the present disclosure is to cover all modifications, equivalents, and alternatives falling within the spirit and scope of the present disclosure. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

In exemplary embodiments of the present disclosure, “at least one of A and B” may refer to “at least one A or B” or “at least one of one or more combinations of A and B”. In addition, “one or more of A and B” may refer to “one or more of A or B” or “one or more of one or more combinations of A and B”.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present disclosure will be described in greater detail with reference to the accompanying drawings. In order to facilitate general understanding in describing the present disclosure, the same components in the drawings are denoted with the same reference signs, and repeated description thereof will be omitted.

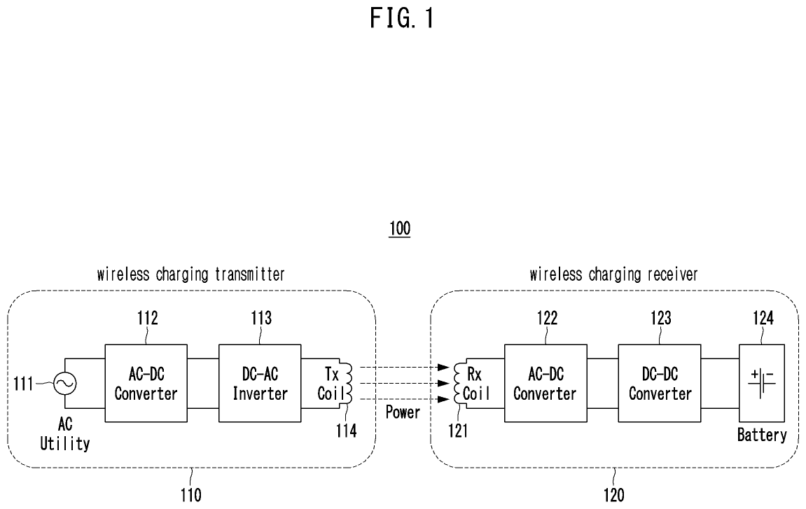

FIG. 1 is a diagram illustrating a wireless charging system according to an embodiment of the present disclosure.

The wireless charging system 100 may include a wireless charging transmitter 110 and a wireless charging receiver 120.

The wireless charging transmitter 110 may also be referred to as the wireless power transmitter. While the wireless charging transmitter can be assumed to be a charging device with a power level in the range of a few kW, it is not limited thereto.

The wireless charging transmitter 110 may include a transmitter power source 111, an AC-DC converter 112, a DC-AC inverter 113, and a transmitter coil 114.

The wireless charging receiver 120 may also be referred to as the wireless power receiver.

The wireless charging receiver 120 may include a receiver coil 121, an AC-DC converter 122, a DC-DC converter 123, and a battery 108.

Wireless charging may be achieved by transferring the power from the transmitter power source 111 to the transmitter coil 114 through the power conversion section, including the AC-DC converter 112 and the DC-AC inverter 113, and then transferring the power to the battery 124 through magnetic induction between the transmitter coil 114 and the receiver coil 121. Typically, the amount of power transferred to the transmitter and receiver coils 114 and 121 may vary depending on factors such as the capacity and charging speed of the battery 124. The DC-AC inverter 113 may be designed according to the power being transferred. To supply appropriate voltage and current to the DC-AC inverter 113, the AC-DC converter 112 may perform power conversion in front of the DC-AC inverter 113. Similarly, the alternating current induced in the receiver coil 121 is converted into direct current through the AC-DC converter 122, and then converted into the required voltage and current for charging the battery 124 through the DC-DC converter 123, thereby charging the battery 124.

A key aspect of power transmission in the wireless charging system 100 is to ensure that there are no foreign objects in the space (charging area) between the transmitter coil 114 and receiver coil 121. If a metallic object enters the charging area, the resonance frequency may change, reducing the transmission efficiency or causing unintended magnetic induction, potentially leading to a fire, which significantly reduces the operational stability of the wireless charging system. Additionally, if a part of a human body, such as a worker's hand, or a living organism, such as an animal, enters the charging area, it may cause harm, why the wireless power transfer standard defines metallic objects and living organisms collectively as foreign objects and specifies the need for accurate detection technology. Thus, to detect unwanted foreign objects within the charging area, an accurate monitoring area must be established.

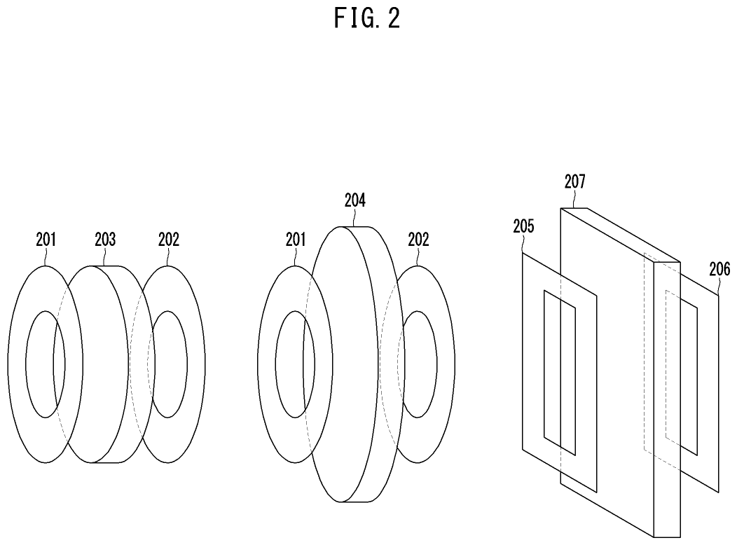

FIG. 2 is a diagram illustrating how the charging area varies with the shape of the coil and the current value, according to an embodiment of the present disclosure.

Hereinafter, descriptions will be made with reference to FIGS. 1 and 2.

Conventionally, an area of interest for foreign object monitoring was set as a fixed region, and monitoring was performed within that fixed monitoring area. However, in the wireless charging system 100, the monitoring area changes based on the current flowing through the transmitter coil 201, which causes the size of the charging area to vary. That is, even though the transmitter coil 201 and receiver coil 202 are the same size, the charging area may vary in size, as denoted by reference numbers 203 and 204, depending on the charging current value. The charging area may also change for coils with different shapes, such as the transmitting coil 205 and receiving coil 206, compared to the transmitting coil 201 and receiving coil 202. Therefore, setting a fixed region as the monitoring area poses the problem of failing to accurately detect foreign objects. Thus, the monitoring area must be set based on an accurate evaluation of the coil shape and charging current value.

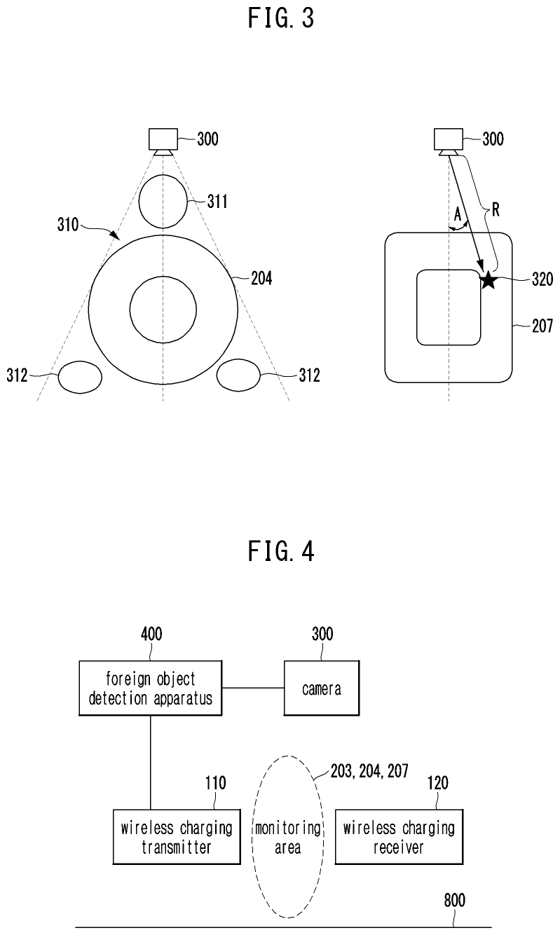

FIG. 3 is a diagram illustrating the problem when monitoring the charging area based on images according to a conventional technology.

Hereinafter, descriptions will be made with reference to FIGS. 2 and 3.

FIG. 3 illustrates the charging areas 204 and 207, which correspond to the charging areas 204 and 207 in FIG. 2, as viewed from the side.

For example, when monitoring the charging areas 204 and 207 through an imaging device 300 (e.g., a camera), the image collected by the camera 300 does not allow for precise determination of the charging area due to the three-dimensional shape of the charging area. As an example, although area 311 is included in the monitoring area 310 due to the field of view of the camera 300, it is not part of the charging areas 204 and 207. Also, area 312 is included in the monitoring area in the two-dimensional flat image, but does not actually correspond to the charging area. Here, the monitoring area 310 may refer to the captured area that includes areas 311 and 312.

To eliminate such unnecessary areas in image-based foreign object detection, a precise evaluation of the distance R between the camera 300 and the foreign object 320, as well as the angle A from the center of the camera 300, is required, as shown on the right side of FIG. 3, and based on this evaluation, it can be determined whether the foreign object 320 is included in the charging areas 204 and 207.

FIG. 4 is a diagram illustrating a foreign object detection system according to an embodiment of the present disclosure.

The charging area of the wireless charging system 100 changes according to the current values flowing through the coils of the transmitter and receiver. Therefore, in order to detect a foreign object entered the changing charging area, it is necessary to update the charging area based on the transmission current value and perform an accurate calculation according to the shape of the coil.

The foreign object detection system for this purpose may include a wireless power transmitter 110, a wireless power receiver 120, a camera 300, and a foreign object detection apparatus 400.

The camera 300 may capture the charging area formed between the wireless power transmitter 110 and the wireless power receiver 120 and send the image to the foreign object detection apparatus 400. Alternatively, in another embodiment, the camera 300 may be part of the foreign object detection apparatus 400.

The foreign object detection apparatus 400 may set or update the charging area as the monitoring area and determine whether a foreign object is located within the monitoring area by evaluating the image obtained from the camera 300. In this case, the monitoring area that is set or updated differs from the one in FIG. 3 in that the actual charging area is set or updated in real-time according to the transmission current value.

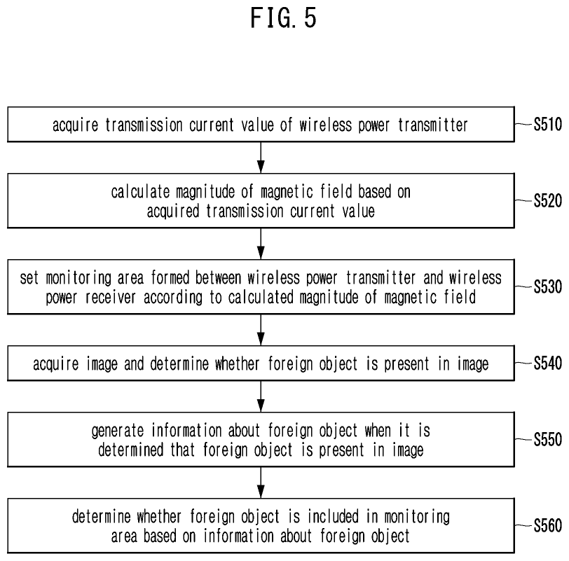

FIG. 5 is a flowchart illustrating the foreign object detection method according to an embodiment of the present disclosure.

Hereinafter, descriptions will be made with reference to FIGS. 4 and 5.

Through operations S510 to S560, the foreign object detection apparatus 400 may update the monitoring area and determine whether a foreign object is included in the updated monitoring area.

In operation S510, the transmission current value of the wireless power transmitter 110 may be acquired. Here, the transmission current value may refer to the measured current of the transmitter coil 114 shown in FIG. 1. The transmission current value may be acquired by the foreign object detection apparatus either through direct measurement, by receiving the current value measured by a separate current measuring device, or from the wireless power transmitter.

In operation S520, based on the acquired transmission current value, the magnitude of the magnetic field (height of the magnetic field area) may be calculated. For example, the magnitude of the magnetic field can be obtained by calculating the height of the magnetic field to be considered from the coil wire according to the Biot-Savart law. Alternatively, the height of the magnetic field area corresponding to the acquired transmission current value may be obtained from a pre-stored table of current value versus magnetic field area height. For example, the magnitude of the magnetic field may be determined by considering factors such as the transmission current value, the number of turns of the coil, and the size of the coil.

In operation S530, the monitoring area formed between the wireless power transmitter 110 and the wireless power receiver 120 according to the calculated magnetic field magnitude may be set or updated. In this case, operation S530 may involve setting or updating the monitoring area in three-dimensional space using the shape of the coil of the wireless power transmitter 110 and the magnitude of the magnetic field.

The process of setting the monitoring area (operations S510 to S530) may occur each time the acquired transmission current value changes or at predetermined time intervals. For this purpose, operation S510 may be performed in real-time, and an additional operation may be included between operations S510 and S520 to determine whether there has been a change in the transmission current value from the current time to the previous time.

In operation S540, an image is acquired, and it may be determined whether a foreign object is present in the image.

In operation S550, when it is determined that a foreign object is present in the image, information about the foreign object may be generated. This information about the foreign object may include the angle between the centerline of the camera capturing the area containing the monitoring area and the center point of the foreign object on the reference plane, as well as the distance between the camera and the foreign object. In this case, the reference plane 601 may be, for example, the floor or ground surface.

In operation S560, based on the information about the foreign object, it may be determined whether the foreign object is included in the set monitoring area. In other words, operation S560 may involve determining whether the foreign object is included in the set monitoring area based on the angle and distance.

In this case, when it is determined in operation S560 that the foreign object is included in the set monitoring area, a foreign object detection alert may be generated. Furthermore, the foreign object detection apparatus 400 may provide a signal to the wireless power transmitter 110 or a separate device supplying power to the wireless power transmitter 110 to block the transmission power of the wireless power transmitter 110. Subsequently, by removing the foreign object, it is possible to ensure the safety of the wireless charging system can be ensured.

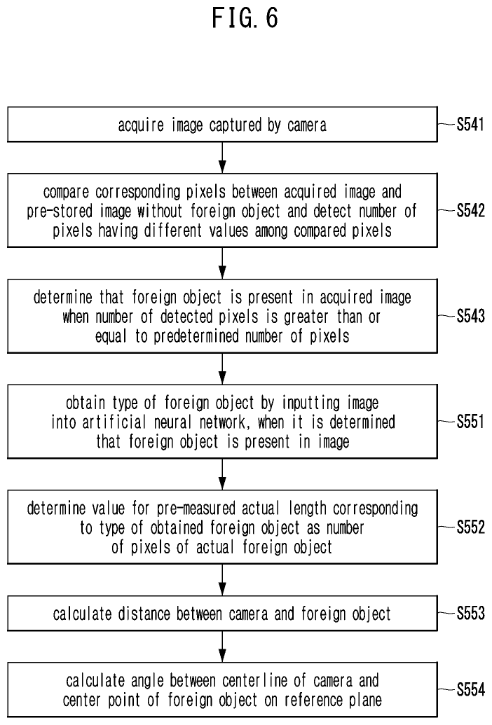

FIG. 6 is a flowchart illustrating the process of monitoring foreign objects according to an embodiment of the present disclosure.

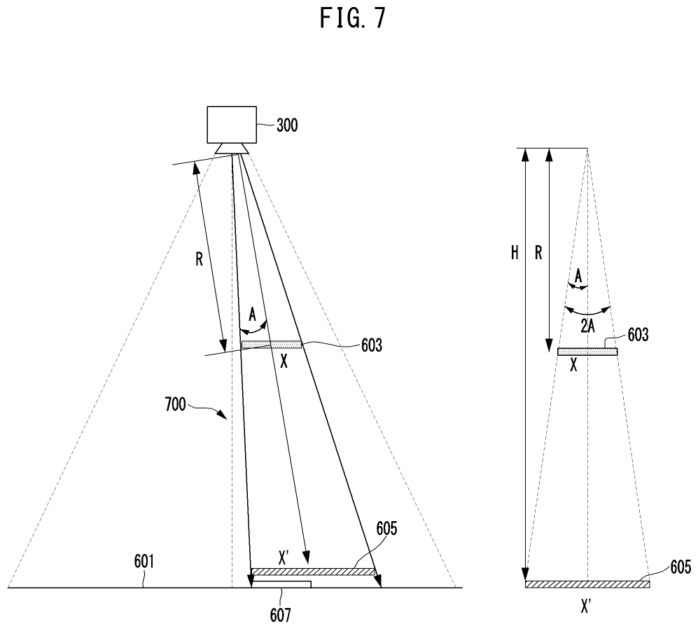

FIG. 7 is a diagram illustrating the process of generating information about foreign objects according to an embodiment of the present disclosure.

Hereinafter, descriptions will be made with reference to FIGS. 6 and 7.

The above-described operation S540 may include operations S541 to S543.

In operation S541, an image captured by the camera 300 may be acquired.

In operation S542, the acquired image may be compared with a pre-stored foreign-object-free image by analyzing corresponding pixels, and the number of pixels with differing values may be detected. Here, the pre-stored foreign-object-free image may be a camera frame captured in the absence of any foreign objects.

In operation S543, when the number of detected pixels is greater than or equal to a predetermined number of pixels, the acquired image may be determined to contain a foreign object.

The above-described operation S550 may include operations S551 to S554.

In operation S551, when it is determined that the foreign object is present in the image, the image containing the foreign object may be input into a pre-trained artificial neural network to obtain the type of foreign object. Various conventional techniques may be used to determine the type of foreign object using the artificial neural network. The artificial neural network may be trained on foreign objects (i.e., learning images including foreign objects) that commonly appear in the operating environment of the wireless charging system (or wireless power transmission system). For example, such foreign objects may include tools such as screws, bolts, screwdrivers, and pliers, a part of a worker's body, such as hands, or small animals.

In operation S552, a value for the actual length, which has been pre-measured for each type of foreign object, may be determined as the number of pixels of an actual foreign object. Alternatively, the actual length of the foreign object may also be calculated using other conventional techniques.

In operation S553, the distance between the camera 300 and the foreign object 603 may be calculated. Here, the camera 300 may be either a distortion-free lens or a distortion lens. The foreign object 603 refers to the actual foreign object. The actual foreign object 603 shown in FIG. 7 may be represented as a virtual foreign object 605 projected onto the reference plane 601 as a result of being captured by the camera 300. That is, the virtual foreign object 605 may be considered as the result of projecting the actual foreign object 603 onto the reference plane 601 along the optical path through which the camera 300 captures the object. In this case, the reference plane 601 may be, for example, the floor or ground surface. The reference plane 601 refers to the expected plane that the camera would capture when there are no foreign objects or obstacles, serving as the reference plane for measuring the distance between the camera 300 and the virtual foreign object 605.

When translated parallel to the reference plane 601, the actual foreign object 603 may be represented as the translated foreign object 607, and its size may differ from the virtual foreign object 605 projected onto the reference plane 601, depending on the distance to the camera 300.

For example, when the camera 300 uses a distortion-free lens, the number of pixels (x′) of the virtual foreign object 605 projected onto the reference plane 601, the number of pixels (x) of the actual foreign object 603, and the distance H between the camera 300 and the reference plane 601 may be used to calculate the distance R between the camera and the actual foreign object 603. Here, the distance H specifically refers to the distance between the camera 300 and the center of the virtual foreign object 605 projected onto the image 601, which may be measured in advance. Therefore, by extracting the length of the virtual foreign object 605 projected onto the reference plane 601, i.e., the number of pixels (x′) in the reference direction, the distance R may be calculated by comparing it with the pre-measured actual length (corresponding to the number of pixels) (x) for each type of foreign object as determined in operation S552. For example, the distance R may be calculated using trigonometric functions or proportional equations. For example, R=Hx/x′ may be used. In this case, the reference direction may refer to the direction of a reference line perpendicular to an imaginary connection line between the wireless power transmitter 110 and the wireless power receiver 120 on the reference plane 800.

For example, when the camera 300 uses a distorted lens, the distance H between the camera 300 and the reference plane 601, along with the pre-measured length (x′) of the foreign object on the reference plane for each type of foreign object, may be used to calculate the distance R between the camera and the foreign object by applying an interpolation technique. Specifically, the distance H and the various foreign object lengths (x′) on the reference plane may be pre-measured and stored in a table, and based on this table, the distance R between the camera and the foreign object can be calculated using interpolation techniques. In this case, the length (or size) of the foreign object on the reference plane refers to the length (or size) of the foreign object as projected onto the reference plane.

By using the distances H and R, the position of the foreign object relative to the reference plane may be determined.

In operation S554, the angle between the centerline 700 of the camera 300 and the center point of the virtual foreign object 605 projected onto the reference plane 601 may be calculated. Specifically, the angle may be calculated based on the camera's field of view (FOV) and the number of pixels in the reference direction of the image.

For example, it may be assumed that the camera 300 has a 90-degree field of view (FOV), and the image was captured with a resolution of 640×480 pixels. In this case, the horizontal pixel count is 640, and the angle for one pixel from the centerline 700 of the camera 300 is calculated as (FOV)/(horizontal pixel count), resulting in 90°/640 pixels=0.140625° per pixel. Therefore, when the virtual foreign object 605 projected onto the image 601 has a length of 100 pixels, the angle (2A) is approximately 14°, and the angle (A) is approximately half of 14°, which is about 7°.

Although the calculations of distance/position and angle in operations S553 and S554 are described using a pixel-based method, various conventional techniques may alternatively be used. For example, in other embodiments, a method of extracting foreign object depth information using two or more cameras may be used.

Referring back to FIG. 5 and FIG. 6, when it is determined in operation S540 that no foreign object is detected in the image, the foreign object monitoring may be suspended. Even when it is determined in operation S560 that the detected foreign object is not included within the set or updated monitoring area, the foreign object monitoring may also be suspended. In this case, operation S540 may be performed again to determine when a foreign object is detected in the newly captured image.

With reference to FIGS. 3 and 7, the lens of camera 300, the monitoring area, and the reference plane 800 are positioned on a straight line, with the wireless power transmitter 110 either spaced a predetermined distance from the reference plane or placed in contact with the reference plane.

Conventionally, as shown in FIG. 3, when the charging device is spaced away from the reference plane, creating a space (e.g., 312), it was difficult to accurately estimate the position of a detected foreign object in the camera image due to the empty space. The present disclosure has been conceived to solve this problem.

Based on the real-time transmission current value measured at the charging device, a decrease in the transmission current value indicates the possibility of a foreign object affecting the magnetic field in the monitoring area, so the presence of the foreign object is determined using the above-described method, allowing for direct or indirect verification or supplementation of the position estimation results.

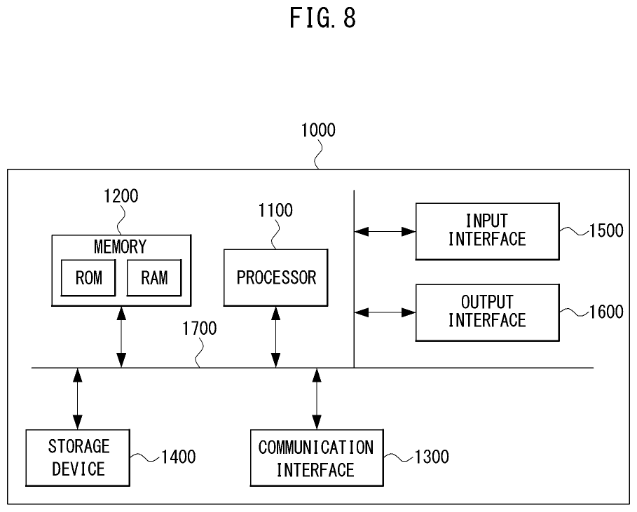

FIG. 8 is a conceptual diagram illustrating an example of a generalized foreign object detection apparatus or computing system capable of performing at least some of the processes from FIGS. 1 to 7.

At least some of the processes of the foreign object detection method according to an embodiment of the present disclosure may be executed by the computing system 1000 of FIG. 8.

With reference to FIG. 8, the computing system 1000 according to an embodiment of the present disclosure may include a processor 1100, memory 1200, a communication interface 1300, storage 1400, an input user interface 1500, an output user interface 1600, and a bus 1700.

The computing system 1000 according to an embodiment of the present disclosure may include at least one processor 1100 and a memory 1200 storing instructions for instructing the at least one processor 1100 to perform at least one step. At least some steps of the method according to an embodiment of the present disclosure may be performed by the at least one processor 1100 loading and executing instructions from the memory 1200.

The processor 1100 may refer to a central processing unit (CPU), a graphics processing unit (GPU), or a dedicated processor on which the methods according to embodiments of the present disclosure are performed.

Each of the memory 1200 and the storage device 1400 may be configured as at least one of a volatile storage medium and a non-volatile storage medium. For example, the memory 1200 may be configured as at least one of read-only memory (ROM) and random access memory (RAM).

Also, the computing system 1000 may include a communication interface 1300 for performing communication through a wireless network.

In addition, the computing system 1000 may further include a storage device 1400, an input interface 1500, an output interface 1600, and the like.

In addition, the components included in the computing system 1000 may each be connected to a bus 1700 to communicate with each other.

The computing system of the present disclosure may be implemented as a communicable desktop computer, a laptop computer, a notebook, a smart phone, a tablet personal computer (PC), a mobile phone, a smart watch, a smart glass, an e-book reader, a portable multimedia player (PMP), a portable game console, a navigation device, a digital camera, a digital multimedia broadcasting (DMB) player, a digital audio recorder, a digital audio player, digital video recorder, digital video player, a personal digital assistant (PDA), etc.

The operations of the method according to the exemplary embodiment of the present disclosure can be implemented as a computer readable program or code in a computer readable recording medium. The computer readable recording medium may include all kinds of recording apparatus for storing data which can be read by a computer system. Furthermore, the computer readable recording medium may store and execute programs or codes which can be distributed in computer systems connected through a network and read through computers in a distributed manner.

The computer readable recording medium may include a hardware apparatus which is specifically configured to store and execute a program command, such as a ROM, RAM or flash memory. The program command may include not only machine language codes created by a compiler, but also high-level language codes which can be executed by a computer using an interpreter.

Although some aspects of the present disclosure have been described in the context of the apparatus, the aspects may indicate the corresponding descriptions according to the method, and the blocks or apparatus may correspond to the steps of the method or the features of the steps. Similarly, the aspects described in the context of the method may be expressed as the features of the corresponding blocks or items or the corresponding apparatus. Some or all of the steps of the method may be executed by (or using) a hardware apparatus such as a microprocessor, a programmable computer or an electronic circuit. In some embodiments, one or more of the most important steps of the method may be executed by such an apparatus.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure is merely exemplary in nature and, thus, variations that do not depart from the substance of the disclosure are intended to be within the scope of the disclosure. Such variations are not to be regarded as a departure from the spirit and scope of the disclosure. Thus, it will be understood by those of ordinary skill in the art that various changes in form and details may be made without departing from the spirit and scope as defined by the following claims.

What is claimed is:

1. A foreign object detection method comprising:
acquiring a transmission current value of a wireless power transmitter;
calculating a magnitude of a magnetic field based on the acquired transmission current value;
setting a monitoring area formed between the wireless power transmitter and a wireless power receiver according to the calculated magnitude of the magnetic field;
acquiring an image and determining whether a foreign object is present in the image;
generating information about the foreign object when it is determined that the foreign object is present in the image; and
determining whether the foreign object is included in the monitoring area based on the information about the foreign object.

2. The foreign object detection method of claim 1, further comprising stopping transmission power of the wireless power transmitter upon determining that the foreign object is included in the monitoring area.

3. The foreign object detection method of claim 1, wherein the setting of the monitoring area comprises setting or updating the monitoring area using three-dimensional spatial variables based on a shape of a coil of the wireless power transmitter and the magnitude of the magnetic field.

4. The foreign object detection method of claim 1, wherein the information about the foreign object comprises an angle between a centerline of a camera capturing an area including the monitoring area and a center point of a virtual foreign object projected onto a reference plane, and a distance between the camera and the foreign object,
and the determining of whether the foreign object is included in the monitoring area is based on the angle and the distance.

5. The foreign object detection method of claim 4, wherein the determining of whether the foreign object is present in the image comprises:
comparing corresponding pixels between the acquired image and a pre-stored image without any foreign object;
detecting the number of pixels among the compared pixels that have different values; and
determining that the foreign object is present in the image when the number of detected pixels is greater than or equal to a predetermined number of pixels.

6. The foreign object detection method of claim 4, wherein the camera is a distortion-free lens, and the generating of the information about the foreign object comprises:
calculating the distance between the camera and an actual foreign object based on the number of pixels of the virtual foreign object projected onto the reference plane in the image, the number of pixels of the actual foreign object, and a distance between the camera and the reference plane; and
calculating the angle between the centerline of the camera and the center point of the virtual foreign object projected onto the reference plane in the image, based on the camera's field of view and the number of pixels in a reference direction of the image.

7. The foreign object detection method of claim 6, wherein the generating of the information about the foreign object comprises:
inputting the image containing the foreign object into an artificial neural network to obtain a type of the foreign object; and
determining a value of a pre-measured actual length corresponding to type of the obtained foreign object as the number of pixels of the actual foreign object using a value of a pre-measured actual length for each type.

8. The foreign object detection method of claim 4, wherein the camera is a distorted lens, and the generating of the information about the foreign object comprises: calculating the distance between the camera and the foreign object using an interpolation method based on a distance between the camera and the reference plane and the pre-measured length of the virtual foreign object projected onto the reference plane for each type of foreign object.

9. The foreign object detection method of claim 4, wherein a lens of the camera, the monitoring area, and the reference plane are positioned in a straight line, and the wireless power transmitter is spaced apart by a predetermined distance from the reference plane.

10. The foreign object detection method of claim 1, further comprising generating a foreign object detection alarm upon determining that the foreign object is included in the monitoring area.

11. A foreign object detection apparatus comprising:
a processor configured to acquire a transmission current value of a wireless power transmitter, calculate a magnitude of a magnetic field based on the acquired transmission current value, set a monitoring area formed between the wireless power transmitter and a wireless power receiver according to the calculated magnitude of the magnetic field, acquire an image and determine whether a foreign object is present in the image, generate information about the foreign object when it is determined that the foreign object is present in the image, and determine whether the foreign object is included in the monitoring area based on the information about the foreign object.

12. The foreign object detection apparatus of claim 11, wherein transmission power of the wireless power transmitter is cut off upon determining that the foreign object is included in the monitoring area.

13. The foreign object detection apparatus of claim 11, wherein the processor sets or updates the monitoring area by defining the monitoring area as a three-dimensional spatial variable based on a shape of a coil of the wireless power transmitter and the magnitude of the magnetic field.

14. The foreign object detection apparatus of claim 11, further comprising a camera, wherein the image is captured by the camera, and the information about the foreign object comprises an angle between the centerline of the camera that captures an area including the monitoring area and a center point of the virtual foreign object projected onto a reference plane and the distance between the camera and the foreign object, and the processor determines whether the foreign object is included in the monitoring area based on the angle and the distance.

15. The foreign object detection apparatus of claim 14, wherein, when determining whether the foreign object is present in the image, the processor compares corresponding pixels between the acquired image and a pre-stored image without any foreign object, detects the number of pixels among the compared pixels that have different values, and determines that the foreign object is present in the image when the number of detected pixels is greater than or equal to a predetermined number of pixels.

16. The foreign object detection apparatus of claim 14, wherein the camera is a distortion-free lens, and the processor calculates the distance between the camera and an actual foreign object based on the number of pixels of the virtual foreign object projected onto the reference plane in the image, the number of pixels of the actual foreign object, and a distance between the camera and the reference plane, and calculates the angle between the centerline of the camera and the center point of the virtual foreign object projected onto the reference plane in the image, based on the camera's field of view and the number of pixels in a reference direction of the image.

17. The foreign object detection apparatus of claim 16, further comprising an artificial neural network,
wherein the processor inputs the image containing the foreign object into the artificial neural network to obtain a type of the foreign object, and determines a value of a pre-measured actual length corresponding to the type of the obtained foreign object as the number of pixels of the actual foreign object using a value of a pre-measured actual length for each type.

18. The foreign object detection apparatus of claim 14, wherein the camera is a distortion lens, and the processor calculates the distance between the camera and the foreign object using an interpolation method based on a distance between the camera and the reference plane and the pre-measured length of the virtual foreign object projected onto the reference plane for each type of foreign object.

19. The foreign object detection apparatus of claim 14, wherein a lens of the camera, the monitoring area, and the reference plane are positioned in a straight line, and the wireless power transmitter is spaced apart by a predetermined distance from the reference plane.

20. The foreign object detection apparatus of claim 11, wherein the processor generates a foreign object detection alarm upon determining that the foreign object is included in the monitoring area.
